(19) United States
(12) Patent Application Publication
(10) Pub. No.: US 2022/0035463 A1
(43) Pub. Date: Feb. 3, 2022

(54) ELECTROMAGNETIC PEN

(71) Applicant: HANVON UGEE TECHNOLOGY CO., LTD., Shenzhen Guangdong (CN)

(72) Inventors: Yuanzhi LI, Shenzhen Guangdong (CN); Liming DENG, Shenzhen Guangdong (CN)

(73) Assignee: HANVON UGEE TECHNOLOGY CO., LTD., Shenzhen Guangdong (CN)

(21) Appl. No.: 17/277,550

(22) PCT Filed: Oct. 18, 2018
(86) PCT No.: PCT/CN2018/110834

§ 371 Date: Mar. 18, 2021

(30) Foreign Application Priority Data
Sep. 19, 2018 (CN) 201811094870.4

(51) Int. Cl. G06F 3/0354; H05K 7/14; H01F 27/24; H01F 27/28

(52) U.S. Cl. CPC G06F 3/03545; H01F 27/28; H01F 27/24; H05K 7/1427

(57) ABSTRACT

Disclosed is an electromagnetic pen, including a housing and a pen body located in the housing, the housing includes a front housing and a rear housing, the pen body includes a pen core, a first iron core, an iron core holder, and a PCBA circuit board, a coil is wound outside the first iron core, the first iron core is fixed at an end of the iron core holder close to a pen tip of the pen core, a second iron core is disposed in the iron core holder, and the pen core is configured to pass through a center of the first iron core, and then drive the second iron core to move; and an elastic structure is disposed between the PCBA circuit board and the iron core holder, a clamping slot is disposed on the PCBA circuit board.

### CROSS-REFERENCE TO RELATED APPLICATIONS

This application is a national stage filing under 35 U.S.C. § 371 of international application number PCT/CN2018/110834, filed Oct. 18, 2018, which claims priority to Chinese patent application No. 201811094870.4, filed Sep. 19, 2018. The contents of these applications are incorporated herein by reference in their entirety.

### TECHNICAL FIELD

The present disclosure relates to the field of information input devices, and more particularly, to an electromagnetic pen.

### BACKGROUND

With the rapid development of computer technology, various hardware devices are changing with each passing day and emerging in endlessly. In input devices, there are various handwriting and drawing input devices to be more beneficial for input needs of handwriting and drawing, including a handwriting board, a drawing board, and the like, which can be collectively called the “drawing board”.

The drawing board may be divided into a resistive type, a capacitive type, an electromagnetic type, a surface acoustic wave type, an optical (infrared) type, and the like in technology, wherein the electromagnetic type is most widely used, and has been recognized by the market. The electromagnetic drawing board is further divided into an active type and a passive type. Accordingly, an electromagnetic pen included in an electromagnetic drawing board system is also divided into an active type and a passive type. A change of a frequency of the passive electromagnetic pen may be implemented by a variable capacitance technology or a variable inductance technology. In the electromagnetic drawing board system adopting the variable inductance technology of the passive electromagnetic pen, a changed inductor is connected in parallel with a capacitor on a PCBA initially. An antenna board may emit a frequency to charge the pen, when the antenna board stops emitting, the pen may be changed from receiving energy to emitting energy, and the inductor on the pen is changed, and is connected in parallel with the fixed capacitor on the PCBA, which may change a frequency emitted by the pen, such that the antenna board is capable of obtaining different frequencies of the pen, and different changes of a pressure value of the pen (reflecting a weight sense) are generated.

The variable inductance technology of the passive electromagnetic pen is mostly used in a coil-wound solenoid, and an inductance value is changed by moving an iron core in the solenoid; or in two iron cores on a same axis, one iron core is wound with a coil, and the other iron core is not wound with a coil, and the inductance value is changed by changing a distance between the two iron cores. Since the coil needs to be wound on the solenoid in the former, a diameter of the pen may be larger than that of the pen in the latter. In addition, the coil is wound on the solenoid in the former, which increases a distance between the coil and the iron core, such that energy loss of the former is larger than that of the latter.

However, at present, the electromagnetic pen adopting a distance relationship structure of two iron cores is composed of many parts, each part has its own manufacturing error, and each part is made of different materials. Therefore, a problem of size inconsistency often occurs during assembly and production, which leads to a condition that an actual size of the electromagnetic pen in delivery is smaller than or larger than a standard size, thereby being not conducive to mass production.

### SUMMARY

In order to address the above technical problem, the present disclosure aims to provide an electromagnetic pen with a good size consistency.

The technical solution adopted in the present disclosure is as follows: an electromagnetic pen includes a housing and a pen body located in the housing, wherein the housing includes a front housing and a rear housing, the pen body includes a pen core, a first iron core, an iron core holder, and a PCBA circuit board, a coil is wound outside the first iron core, the first iron core is fixed at an end of the iron core holder close to a pen tip of the pen core, a second iron core is disposed in the iron core holder, and the pen core is configured to pass through a center of the first iron core, and then drive the second iron core to move; and an elastic structure is disposed between the PCBA circuit board and the iron core holder, a clamping slot is disposed on the PCBA circuit board, and an end portion matched with the clamping slot is disposed on the rear housing.

Further, a screw post is disposed behind the iron core holder, a screw hole is disposed in the PCBA circuit board, and the screw post is fixed in the screw hole by a screw.

Further, a thin film sheet is also disposed between the first iron core and the second iron core.

Further, a pen core clamp is also disposed in the iron core holder, and the pen core clamp is located behind the second iron core.

Further, a step is provided at a tail end of the pen core.

Further, a first through hole is formed in the center of the first iron core, a second through hole is formed in a center of the second iron core, and a diameter of the first through hole is larger than that of the second through hole.

Further, an outer diameter of the first iron core is smaller than that of the second iron core.

Further, the elastic structure adopts a silicone ring.

Further, the screw post is a cylinder, and the screw hole is an elliptical hole.

The present disclosure has the beneficial effects that: according to the electromagnetic pen of the present disclosure, the clamping slot is disposed on the PCBA circuit board of the pen body, and the end portion matched with the clamping slot is disposed on the rear housing, such that the rear housing pushes the pen body against the front housing when the front housing and the rear housing are combined by matching the clamping slot with the end portion, and the front housing is capable of being tightly attached or connected to the rear housing; and the elastic structure is additionally disposed between the iron core holder of the front housing and the PCBA circuit board, a manufacturing error of each part in an axial direction from the pen tip to a pen tail of the pen core is eliminated by an elastic margin of the elastic structure, such that an actual size of the electromagnetic pen in delivery is equal to a standard size, thereby being conductive to batch production, and meanwhile, the elastic structure may also play a role of buffering, thereby reducing a probability that the parts are damaged due to mechanical shock or wear, and prolonging a service life of the electromagnetic pen.

### BRIEF DESCRIPTION OF THE DRAWINGS

FIG. 1 is a schematic diagram of an overall structure of an electromagnetic pen of the present disclosure;

FIG. 2 is a stereoscopic exploded view of the electromagnetic pen of the present disclosure;

FIG. 3 is a schematic structural diagram of a PCBA circuit board of the present disclosure; and

FIG. 4 is a schematic structural diagram of a pen body of the electromagnetic pen of the present disclosure after assembly.

### DETAILED DESCRIPTION

The present disclosure is further explained hereinafter with reference to the accompanying drawings and the specific embodiments of the specification.

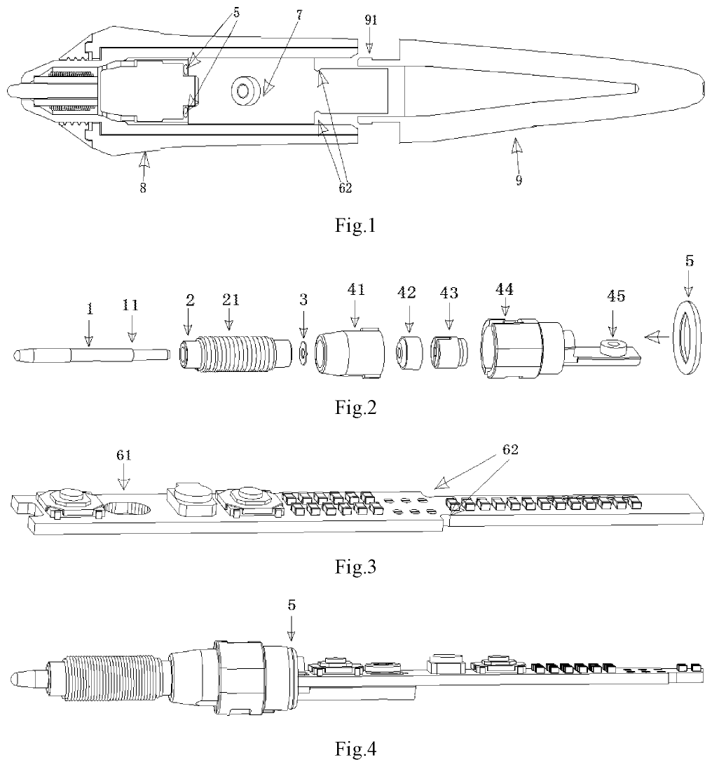

Referring to FIG. 1, FIG. 2, FIG. 3, and FIG. 4, an electromagnetic pen includes a housing and a pen body 7 located in the housing. The housing includes a front housing 8 and a rear housing 9, the pen body 7 includes a pen core 1, a first iron core 2, an iron core holder, and a PCBA circuit board, a coil 21 is wound outside the first iron core 2, the first iron core 2 is fixed at an end of the iron core holder close to a pen tip of the pen core 1, a second iron core 42 is disposed in the iron core holder, and the pen core 1 passes through a center of the first iron core 2, and then drives the second iron core 42 to move. An elastic structure 5 is disposed between the PCBA circuit board and the iron core holder, a clamping slot 62 is disposed on the PCBA circuit board, and an end portion 91 matched with the clamping slot 62 is disposed on the rear housing 9.

An electromagnetic pen with a distance relationship structure of two iron cores is used in the existing technology, which generally adopts a structure that an iron core without a wound coil is close to the pen tip. The pen tip pushes against the iron core without the wound coil, when the pen tip is stressed, the iron core without the wound coil may be forced to approach an iron core with a wound coil, resulting in a change of inductance. However, this structure often leads to a condition that a distance between the two iron cores cannot be too large, such that only an elastic element made of a very thin elastic material can be placed. After long-term use, the elastic element may fatigue elastically, causing the distance between the two iron cores to get out of control, such that the electromagnetic pen cannot be operated normally.

The distance relationship structure of two iron cores is also used in the electromagnetic pen of the present disclosure to change the inductance, but a difference in structure is that the iron core with the wound coil (i.e., the first iron core) is close to the pen tip, and the pen core passes through the center of the first iron core to push the iron core without the wound coil (i.e., the second iron core). This structure may provide an enough space behind the second iron core to design a pen core clamp, an internal elastic component, and other structures, such that the pen tip has an excellent force feedback performance. In addition, a front end of the pen is a coil-wound iron core structure, and compared with a variable inductance structure that the coil is wound on a solenoid, a diameter of the pen is smaller, such that an appearance of the pen may be made thinner and more beautiful. Compared with the structure that the coil is wound on the solenoid, more energy is also obtained by the pen. There is no too thin elastic component, and the product has a long service life. In the present disclosure, when the second iron core is pushed, an inductance value on the wound coil may be changed, and a changed inductor is connected in parallel with a capacitor on the PCBA circuit board. An antenna board may emit a frequency to charge the pen, when the antenna board stops emitting, the pen may be changed from receiving energy to emitting energy, and the coil-wound inductor on the pen is changed, and is connected in parallel with the fixed capacitor on the PCBA circuit board, which may change a frequency emitted by the pen, such that the antenna board is capable of obtaining different frequencies of the pen, and different changes of a pressure value of the pen are generated.

The PCBA circuit board is electrically connected with the coil 21 to convert the changed inductance into a change of the frequency, such that the antenna board is capable of obtaining different frequencies of the pen, and different pressure values of the pens are generated. Specifically, the PCBA circuit board is located behind the iron core holder, and may be fixedly connected with the iron core holder by a screw.

As shown in FIG. 2, the first iron core 2 and the second iron core 42 of the present disclosure are both a hollow structure, which may accommodate the pen core 1 to move in an axial direction in an interior thereof. The pen tip of the pen core 1 is located on the left, and the tail end is located on the right. As shown in FIG. 2, the iron core holder includes a front portion 41 and a bottom portion 44 which are matched with each other, the first iron core 2 is fixed on the front portion 41 of the iron core holder from a direction of the pen tip, while the second iron core 42 is loaded in the iron core holder from a direction of the pen tail. The first iron core 2 is fixed, and the second iron core 42 may be pushed by the pen core 1 in the iron core holder. The bottom portion 44 is capable of being combined with the front portion 41 in a rotating manner to form the iron core holder.

The clamping slot 62 mainly plays a role of fixing, and is capable of tightly attaching or connecting the front housing to the rear housing. The clamping slot 62 is located at a middle and rear portion of the PCBA circuit board (i.e., the tail end of the pen body 7), and may be clamped with the end portion 91 of the rear housing 9. As shown in FIG. 1 and FIG. 3, when the front housing 8 and the rear housing 9 are combined, the end portion 91 of the rear housing 9 may fixed by the clamping slot 62 through clamping, thereby pushing the whole pen body 7 against the front housing 8.

The elastic structure 5 has a certain elastic margin, which is used for eliminating and absorbing an error in an axial direction from the pen tip to the pen tail of the electromagnetic pen, such that an actual size of the electromagnetic pen in delivery is equal to a standard size. In addition, the elastic structure 5 may also play a role of buffering, which prevents the rear housing, the iron core holder, and other parts from being damaged due to mechanical shock or wear, thereby prolonging a service life. The elastic structure 5 may be implemented by a rubber ring (such as a silicone ring), an elastic metal sheet, a thin film sheet, and other elastic structures.

Referring to FIG. 2 and FIG. 3, further, as a preferred embodiment, a screw post 45 is disposed behind the iron core holder, a screw hole 61 is disposed in the PCBA circuit board, and the screw post 45 is fixed in the screw hole 61 by a screw.

Referring to FIG. 2, further, as a preferred embodiment, a thin film sheet 3 is also disposed between the first iron core 2 and the second iron core 42.

A fixed and accurate distance must be kept between the first iron core 2 and the second iron core 42 of the present disclosure when the pen core 1 is not used for writing, such that the thin film sheet 3 with an accurate thickness is sandwiched therebetween to ensure the distance between the two iron cores.

Referring to FIG. 2, further, as a preferred embodiment, a pen core clamp 43 is also disposed in the iron core holder, and the pen core clamp 43 is located behind the second iron core 42.

The pen core clamp 43 of the present disclosure is used for clamping the pen core 1.

Referring to FIG. 2, further, as a preferred embodiment, a step 11 is provided at a tail end of the pen core 1.

The step 11 is used for pushing the second iron core 42.

Referring to FIG. 2, further, as a preferred embodiment, a first through hole is formed in the center of the first iron core 2, a second through hole is formed in a center of the second iron core 42, and a diameter of the first through hole is larger than that of the second through hole.

In the present disclosure, the diameter of the first through hole of the first iron core 2 is larger than that of the second through hole of the second iron core 42, such that the pen core 1 is capable of pushing the second iron core 42 by the step 11 at the tail end of the pen core 1.

Further, as a preferred embodiment, an outer diameter of the first iron core is smaller than that of the second iron core.

In the present disclosure, the outer diameter of the second iron core without the wound coil is larger than that of the first iron core with the wound coil. The outer diameter of the second iron core is reduced close to one end of the first iron core, such that an overall appearance of the pen may not be abrupt due to the second iron core without the wound coil in the interior, thereby having a better consistency in overall appearance.

Referring to FIG. 1 and FIG. 2, further, as a preferred embodiment, the elastic structure 5 adopts a silicone ring.

Further, as a preferred embodiment, the screw post is a cylinder, and the screw hole is an elliptical hole.

In the present disclosure, the screw hole in the PCBA circuit board is the elliptical hole, and the screw post of the iron core holder is the cylinder, such that the PCBA circuit board is also capable of moving towards the pen tip or the pen tail for a small distance after the screw is tightened (a characteristic of the elliptical hole), thereby facilitating position regulation during installation and reducing installation errors.

The working principle of the electromagnetic pen of the present disclosure is as follows: when the pen tip of the pen core is stressed during writing, the pen core passes through the center of the first iron core and the center of the second iron core, and then is clamped by the pen core clamp, and the second iron core is pushed to move in the axial direction by the step at the tail end of the pen core, such that different distances are formed between the first iron core and the second iron core, thereby changing the inductance value on the coil. The changed inductor is connected in parallel with the fixed capacitor on the PCBA circuit board, such that the frequency emitted by the pen is changed, and different changes of a pressure value of the pen are generated. In addition, the clamping slot is disposed on the PCBA circuit board of the pen body of the present disclosure, and the end portion matched with the clamping slot is disposed on the rear housing, such that the rear housing pushes the pen body against the front housing when the front housing and the rear housing are combined by matching the clamping slot with the end portion, and the front housing is capable of being tightly attached or connected to the rear housing. The elastic structure is additionally disposed between the iron core holder of the front housing and the rear housing, the manufacturing error of each part in the axial direction from the pen tip to the pen tail of the pen core is eliminated by the elastic margin of the elastic structure, such that an actual size of the electromagnetic pen in delivery is equal to a standard size, thereby being conductive to batch production, and increasing a production first pass yield. Meanwhile, the elastic structure may also play a role of buffering, thereby reducing a probability that the parts are damaged due to mechanical shock or wear, and extending a service life of the electromagnetic pen.

The foregoing describes the preferred embodiments of the present disclosure in detail, but the present disclosure is not limited to the embodiments. Those skilled in the art may further make various equivalent modifications or substitutions without violating the spirit of the present disclosure, and these equivalent modifications or substitutions are all included in the scope defined by the claims of the present application.

1. An electromagnetic pen, comprising:
a housing; and
a pen body located in the housing,
wherein the housing comprises a front housing and a rear housing, the pen body comprises a pen core, a first iron core, an iron core holder, and a PCBA circuit board, a coil is wound outside the first iron core, the first iron core is fixed at an end of the iron core holder close to a pen tip of the pen core, a second iron core is disposed in the iron core holder, and the pen core is configured to pass through a center of the first iron core, and then drive the second iron core to move; and
wherein an elastic structure is disposed between the PCBA circuit board and the iron core holder, a clamping slot is disposed on the PCBA circuit board, and an end portion matched with the clamping slot is disposed on the rear housing.

2. The electromagnetic pen of claim 1, wherein a screw post is disposed behind the iron core holder, a screw hole is disposed in the PCBA circuit board, and the screw post is fixed in the screw hole by a screw.

3. The electromagnetic pen of claim 1, wherein a thin film sheet is disposed between the first iron core and the second iron core.

4. The electromagnetic pen of claim 3, wherein a pen core clamp is disposed in the iron core holder, and the pen core clamp is located behind the second iron core.

5. The electromagnetic pen of claim 4, wherein a step is provided at a tail end of the pen core.

6. The electromagnetic pen of claim 1, wherein a first through hole is formed in the center of the first iron core, a second through hole is formed in a center of the second iron core, and a diameter of the first through hole is larger than that of the second through hole.

7. The electromagnetic pen of claim 1, wherein an outer diameter of the first iron core is smaller than that of the second iron core.

8. The electromagnetic pen of claim 1, wherein the elastic structure adopts a silicone ring.

9. The electromagnetic pen of claim 2, wherein the screw post is a cylinder, and the screw hole is an elliptical hole.

10. The electromagnetic pen of claim 2, wherein a first through hole is formed in the center of the first iron core, a second through hole is formed in a center of the second iron core, and a diameter of the first through hole is larger than that of the second through hole.

11. The electromagnetic pen of claim 3, wherein a first through hole is formed in the center of the first iron core, a second through hole is formed in a center of the second iron core, and a diameter of the first through hole is larger than that of the second through hole.

12. The electromagnetic pen of claim 4, wherein a first through hole is formed in the center of the first iron core, a second through hole is formed in a center of the second iron core, and a diameter of the first through hole is larger than that of the second through hole.

13. The electromagnetic pen of claim 5, wherein a first through hole is formed in the center of the first iron core, a second through hole is formed in a center of the second iron core, and a diameter of the first through hole is larger than that of the second through hole.

14. The electromagnetic pen of claim 2, wherein an outer diameter of the first iron core is smaller than that of the second iron core.

15. The electromagnetic pen of claim 3, wherein an outer diameter of the first iron core is smaller than that of the second iron core.

16. The electromagnetic pen of claim 4, wherein an outer diameter of the first iron core is smaller than that of the second iron core.

17. The electromagnetic pen of claim 5, wherein an outer diameter of the first iron core is smaller than that of the second iron core.

18. The electromagnetic pen of claim 2, wherein the elastic structure adopts a silicone ring.

19. The electromagnetic pen of claim 3, wherein the elastic structure adopts a silicone ring.

20. The electromagnetic pen of claim 4, wherein the elastic structure adopts a silicone ring.
